(19) United States
(12) Patent Application Publication
(10) Pub. No.: US 2023/0263000 A1
(43) Pub. Date: Aug. 17, 2023

(54) LIGHT-EMITTING DEVICE AND METHOD OF PRODUCING LIGHT-EMITTING DEVICE

(71) Applicant: SHARP KABUSHIKI KAISHA, Sakai City, Osaka (JP)

(72) Inventors: JUN SAKUMA, Sakai City, Osaka (JP); YASUSHI ASAOKA, Sakai City, Osaka (JP)

(21) Appl. No.: 18/015,038

(22) PCT Filed: Jul. 20, 2020
(86) PCT No.: PCT/JP2020/028018

§ 371 Date: Jan. 6, 2023

(51) Int. Cl. H10K 50/13; H10K 50/115; H10K 71/10; H10K 59/35; C09K 11/88; C09K 11/70; C09K 11/08

(52) U.S. Cl. CPC H10K 50/131; H10K 50/115; H10K 71/10; H10K 59/35; C09K 11/883; C09K 11/70; C09K 11/0883; B82Y 20/00

(57) ABSTRACT

A light-emitting device includes a first light-emitting region in which a light emission peak wavelength is a first wavelength; a second light-emitting region in which a light emission peak wavelength is a second wavelength shorter than the first wavelength; a cathode disposed in the first light-emitting region and the second light-emitting region; an anode facing the cathode in the first light-emitting region and the second light-emitting region; a second light-emitting layer disposed between the cathode and the anode in the first light-emitting region and the second light-emitting region and having a light emission peak wavelength being the second wavelength; a first light-emitting layer disposed between the anode and the second light-emitting layer at least in the first light-emitting region and having a light emission peak wavelength being the first wavelength; and a first electron transport layer disposed between the first light-emitting layer and the second light-emitting layer in the first light-emitting region and having ionization energy higher than both of ionization energy of the first light-emitting layer and ionization energy of the second light-emitting layer.

### TECHNICAL FIELD

The present invention relates to a light-emitting device and a manufacturing method of the light-emitting device.

### BACKGROUND ART

For example, PTL 1 discloses a manufacturing method of a light-emitting device which includes at least a first light-emitting layer and a second light-emitting layer and for which lithography where each of the light-emitting layers is lifted off with a resist layer is used.

### CITATION LIST

### Patent Literature

PTL 1: JP 2009-088276 A

### SUMMARY OF INVENTION

### Technical Problem

However, the light-emitting device described in PTL 1 is accompanied by development with a developing solution every time when a light-emitting layer is formed. The formed light-emitting layer is exposed to the developing solution for each development, and may thus be damaged, leading to a decrease in reliability of the light-emitting device.

A main object of the disclosure is to provide a highly reliable light-emitting device in which damage due to lithography in a light-emitting layer and the like can be suppressed, for example.

### Solution to Problem

A light-emitting device according to one aspect of the present invention includes a first light-emitting region in which a light emission peak wavelength is a first wavelength; a second light-emitting region in which a light emission peak wavelength is a second wavelength shorter than the first wavelength; a cathode disposed in the first light-emitting region and the second light-emitting region; an anode facing the cathode in the first light-emitting region and the second light-emitting region; a second light-emitting layer disposed between the cathode and the anode and having a light emission peak wavelength being the second wavelength; a first light-emitting layer disposed between the anode and the second light-emitting layer at least in the first light-emitting region and having a light emission peak wavelength being the first wavelength; and a first electron transport layer disposed between the first light-emitting layer and the second light-emitting layer in the first light-emitting region and having ionization energy higher than both of ionization energy of the first light-emitting layer and ionization energy of the second light-emitting layer.

Further, a light-emitting device according to another aspect of the present invention includes a first light-emitting region in which a light emission peak wavelength is a first wavelength; a second light-emitting region in which a light emission peak wavelength is a second wavelength shorter than the first wavelength; a cathode disposed in the first light-emitting region and the second light-emitting region; an anode facing the cathode in the first light-emitting region and the second light-emitting region; a second light-emitting layer disposed between the cathode and the anode in the first light-emitting region and the second light-emitting region and having a light emission peak wavelength being the second wavelength; a first light-emitting layer disposed between the cathode and the second light-emitting layer at least in the first light-emitting region and having a light emission peak wavelength being the first wavelength; and a first hole transport layer disposed between the first light-emitting layer and the second light-emitting layer in the first light-emitting region and having an electron affinity lower than both of an electron affinity of the first light-emitting layer and an electron affinity of the second light-emitting layer.

Furthermore, a manufacturing method of a light-emitting device, according to one aspect of the present invention, includes forming a resist layer on a base material; removing a portion of the resist layer; forming a first light-emitting layer on the base material on which the portion of the resist layer has been removed; forming a charge transport layer covering the first light-emitting layer; and removing a portion of the resist layer covered by the charge transport layer, and forming a second light-emitting layer on the removed portion.

### BRIEF DESCRIPTION OF DRAWINGS

FIG. 1 is a diagram schematically illustrating an example of a layered structure of a light-emitting device according to a first embodiment.

FIG. 2 is a schematic cross-sectional view illustrating a step in an example of a manufacturing method of the light-emitting device according to the first embodiment.

FIG. 3 is a schematic cross-sectional view illustrating a step in the example of the manufacturing method of the light-emitting device according to the first embodiment.

FIG. 4 is a schematic cross-sectional view illustrating a step in the example of the manufacturing method of the light-emitting device according to the first embodiment.

FIG. 5 is a schematic cross-sectional view illustrating a step in the example of the manufacturing method of the light-emitting device according to the first embodiment.

FIG. 6 is a schematic cross-sectional view illustrating a step in the example of the manufacturing method of the light-emitting device according to the first embodiment.

FIG. 7 is a schematic cross-sectional view illustrating a step in the example of the manufacturing method of the light-emitting device according to the first embodiment.

FIG. 8 is a schematic cross-sectional view illustrating a step in the example of the manufacturing method of the light-emitting device according to the first embodiment.

FIG. 9 is a schematic cross-sectional view illustrating a step in the example of the manufacturing method of the light-emitting device according to the first embodiment.

FIG. 10 is a schematic cross-sectional view illustrating a step in the example of the manufacturing method of the light-emitting device according to the first embodiment.

FIG. 11 is a schematic cross-sectional view illustrating a step in the example of the manufacturing method of the light-emitting device according to the first embodiment.

FIG. 12 is a schematic cross-sectional view illustrating a step in the example of the manufacturing method of the light-emitting device according to the first embodiment.

FIG. 13 is a schematic cross-sectional view illustrating a step in the example of the manufacturing method of the light-emitting device according to the first embodiment.

FIG. 14 is a cross-sectional view illustrating a step in the example of the manufacturing method of the light-emitting device according to the first embodiment.

FIG. 15 is a schematic cross-sectional view illustrating a step in the example of the manufacturing method of the light-emitting device according to the first embodiment.

FIG. 16 is an energy level diagram of an example of layers in a first light-emitting region of a light-emitting device according to a first example.

FIG. 17 is an energy level diagram of an example of layers in a second light-emitting region of the light-emitting device according to the first example.

FIG. 18 is an energy level diagram of an example of layers in a first light-emitting region of a light-emitting device according to a second example.

FIG. 19 is an energy level diagram of an example of layers in a second light-emitting region of the light-emitting device according to the second example.

### DESCRIPTION OF EMBODIMENTS

Preferable embodiments for carrying out the present invention will be described hereinafter. However, the following embodiments are merely illustrative. The present invention is not limited to the following embodiments.

### First Embodiment

Hereinafter, an embodiment of the disclosure will be described.

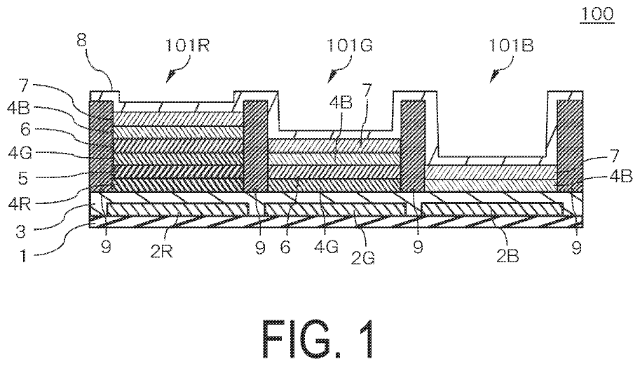

FIG. 1 is a diagram schematically illustrating an example of a layered structure of a light-emitting device 100 according to the present embodiment.

The light-emitting device 100 is a device that emits light. For example, the light-emitting device 100 may be an illumination device (for example, a backlight or the like) that emits light such as white light, or may be a display device that displays an image (including character information and the like, for example) by emitting light. In the present embodiment, an example in which the light-emitting device 100 is one pixel in a display device will be described. For example, a display device can be formed by arranging a plurality of pixels in a matrix.

As illustrated in FIG. 1, the light-emitting device 100 includes, for example, a first light-emitting region 101R, a second light-emitting region 101G, and a third light-emitting region 101B. The first light-emitting region 101R is, for example, a red light-emitting region in which a light emission peak wavelength is a first wavelength (for example, approximately 630 nm). The second light-emitting region 101G is, for example, a green light-emitting region in which a light emission peak wavelength is a second wavelength (for example, approximately 530 nm) shorter than the first wavelength. The third light-emitting region 101B is, for example, a blue light-emitting region in which a light emission peak wavelength is a third wavelength (for example, approximately 440 nm) shorter than the second wavelength. Note that the light emission peak wavelength described above represents, for example, a light emission peak in each light-emitting layer. In the present embodiment, a case where each of the light-emitting regions 101R, 101G, and 101B emits light at the light emission peak wavelength described above will be described; however, the light-emitting regions 101R, 101G, and 101B are not particularly limited thereto.

The first light-emitting region 101R is, for example, a region that emits light at the light emission peak wavelength being the first wavelength (for example, red) in the light-emitting device 100. The first light-emitting region 101R corresponds to, for example, a light-emitting element (for example, a red light-emitting element) that emits light at the light emission peak wavelength being the first wavelength in the light-emitting device 100. The first light-emitting region 101R has a structure in which a substrate 1, a first electrode 2R, a first charge transport layer 3, a first light-emitting layer 4R, a second charge transport layer 5, a second light-emitting layer 4G, a third charge transport layer 6, a third light-emitting layer 4B, a fourth charge transport layer 7, and a second electrode 8 are layered in this order. In other words, the first light-emitting region 101R has a structure in which each of the layers is disposed between a first electrode 2 and the second electrode 8 disposed so as to face the first electrode 2.

The substrate 1 is formed of, for example, glass or the like, and functions as a support body that supports each of the layers described above. The substrate 1 may be, for example, an array substrate in which a thin film transistor (TFT) and the like are formed.

For example, the first electrode 2R injects a first charge into the first light-emitting layer 4R.

For example, the second electrode 8 injects a second charge into the first light-emitting layer 4R. The second charge has polarity opposite to that of the first charge.

The first electrode 2R and the second electrode 8 are formed of, for example, a conductive material such as a metal and a transparent conductive oxide. Examples of the metal described above include Al, Cu, Au, Ag, and the like. Examples of the transparent conductive oxide described above include, for example, indium tin oxide (ITO), indium zinc oxide (IZO), zinc oxide (ZnO), aluminum zinc oxide (ZnO:Al(AZO)), boron zinc oxide (ZnO:B(BZO)), and the like. Note that the first electrode 2R and the second electrode 8 may be, for example, a layered body including at least one metal layer and/or at least one transparent conductive oxide layer.

The first light-emitting layer 4R is disposed between the first electrode 2R and the second electrode 8. The first light-emitting layer 4R has the light emission peak wavelength being the first wavelength, and emits light at, for example, approximately 630 nm. For example, the first light-emitting layer 4R includes a first light-emitting material that has the light emission peak wavelength being the first wavelength and emits light at, for example, approximately 630 nm. The first light-emitting material emits light by, for example, recombination of the first charge injected from the first electrode 2R and the second charge injected from the second electrode 8. In other words, it can be said that the first light-emitting layer 4R emits light by, for example, the recombination of the first charge injected from the first electrode 2R and the second charge injected from the second electrode 8.

Note that, in the first light-emitting region 101R in the present embodiment, the first charge is injected from the first electrode 2R into the first light-emitting layer 4R via the first charge transport layer 3. Meanwhile, in the first light-emitting region 101R in the present embodiment, the second charge is injected from the second electrode 8 into the first light-emitting layer 4R via the fourth charge transport layer 7, the third light-emitting layer 4B, the third charge transport layer 6, the second light-emitting layer 4G, and the second charge transport layer 5. In this way, the first light-emitting layer 4R emits light.

Examples of the first light-emitting material include quantum dots and the like. For example, the quantum dot may be a semiconductor fine particle having a particle size of equal to or less than 100 nm and may include a group II-VI semiconductor compound such as MgS, MgSe, MgTe, MgZnS, MgZnSe, CaS, CaSe, CaTe, SrS, SrSe, SrTe, BaS, BaSe, BaTe, ZnS, ZnSe, ZnTe, ZnSSe, ZnTeS, ZnTeSe, CdS, CdSe, CdSSe, CdTe, CdSeTe, CdZnSe, CdZnTe, HgS, HgSe, and HgTe, and/or a crystal of a group III-V semiconductor compound such as GaAs, GaP, InN, InAs, InP, and InSb, and/or a crystal of a group IV semiconductor compound such as Si and Ge. Further, the quantum dot may have, for example, a core/shell structure in which the semiconductor crystal described above is a core and the core is overcoated with a shell material having a wide band gap. Furthermore, the quantum dot may have a perovskite structure such as APbX₃[A=Cs, methylammonium (MA), formamidinium (FA), X=Cl, Br, I] and (CH₃NH₃)₃Bi₂X₉.

The first charge transport layer 3 is disposed between the first electrode 2R and the first light-emitting layer 4R. The first charge transport layer 3 transports, to the first light-emitting layer 4R, the first charge injected from the first electrode 2R.

The second light-emitting layer 4G is disposed between the first light-emitting layer 4R and the second electrode 8. The second light-emitting layer 4G has the light emission peak wavelength being the second wavelength, and emits light at, for example, approximately 530 nm. For example, the second light-emitting layer 4G includes a second light-emitting material that has the light emission peak wavelength being the second wavelength and emits light at, for example, approximately 530 nm. The second light-emitting material emits light by, for example, recombination of the injected first charge and the injected second charge. In other words, it can be said that the second light-emitting layer 4G emits light by, for example, the recombination of the injected first charge and the injected second charge. Examples of the second light-emitting material include quantum dots and the like similar to the first light-emitting material.

The second charge transport layer 5 is disposed between the first light-emitting layer 4R and the second light-emitting layer 4G. The second charge transport layer 5 transports, to the first light-emitting layer 4R, the second charge injected from the second electrode 8. Furthermore, for example, the second charge transport layer 5 blocks the first charge injected from the first electrode 2R from being transported to the second light-emitting layer 4G. In this way, light emission of the second light-emitting layer 4G can be suppressed in the first light-emitting region 101R. In this way, color mixing in the first light-emitting region 101R can be suppressed.

The third light-emitting layer 4B is disposed between the second light-emitting layer 4G and the second electrode 8. The third light-emitting layer 4B has the light emission peak wavelength being the third wavelength, and emits light at, for example, approximately 440 nm. For example, the third light-emitting layer 4B includes a third light-emitting material that has the light emission peak wavelength being the third wavelength and emits light at, for example, approximately 440 nm. The third light-emitting material emits light by, for example, recombination of the injected first charge and the injected second charge. In other words, it can be said that the second light-emitting layer 4G emits light by, for example, the recombination of the injected first charge and the injected second charge. Examples of the third light-emitting material include quantum dots and the like similar to the first light-emitting material.

The third charge transport layer 6 is disposed between the second light-emitting layer 4G and the third light-emitting layer 4B. The third charge transport layer 6 transports, to the first light-emitting layer 4R, the second charge injected from the second electrode 8. Furthermore, for example, the third charge transport layer 6 blocks the first charge injected from the first electrode 2R from being transported to the third light-emitting layer 4B. In this way, even when the first charge moves through the second charge transport layer 5, light emission of the third light-emitting layer 4B can be suppressed in the first light-emitting region 101R. In this way, color mixing in the first light-emitting region 101R can be suppressed.

The fourth charge transport layer 7 is disposed between the third light-emitting layer 4B and the second electrode 8. The fourth charge transport layer 7 transports, to the first light-emitting layer 4R, the second charge injected from the second electrode 8.

As described above, in the first light-emitting region 101R, the first light-emitting layer 4R emits light, and the second light-emitting layer 4G and the third light-emitting layer 4B emit almost no light, and thus light is emitted at the light emission peak wavelength being the first wavelength.

Subsequently, the second light-emitting region 101G will be described.

The second light-emitting region 101G is, for example, a region that emits light at the light emission peak wavelength being the second wavelength (for example, green) in the light-emitting device 100. The second light-emitting region 101G corresponds to, for example, a light-emitting element (for example, a green light-emitting element) that emits light at the light emission peak wavelength being the second wavelength in the light-emitting device 100. The second light-emitting region 101G has a structure in which the substrate 1, the first electrode 2R, the first charge transport layer 3, the second light-emitting layer 4G, the third charge transport layer 6, the third light-emitting layer 4B, the fourth charge transport layer 7, and the second electrode 8 are layered in this order. In other words, the second light-emitting region 101G has a structure in which each of the layers is disposed between the first electrode 2 and the second electrode 8 disposed so as to face the first electrode 2. Note that the first electrode 2G is similar to the first electrode 2R.

Further, the second light-emitting region 101G has a configuration in which the first electrode 2R is replaced with the first electrode 2G, and the first light-emitting layer 4R and the second charge transport layer 5 are not provided in the configuration of the first light-emitting region 101R.

Note that, in the second light-emitting region 101G in the present embodiment, the first charge is injected from the first electrode 2G into the second light-emitting layer 4G via the first charge transport layer 3. Meanwhile, in the second light-emitting region 101G in the present embodiment, the second charge is injected from the second electrode 8 into the second light-emitting layer 4G via the fourth charge transport layer 7, the second light-emitting layer 4G, and the third charge transport layer 6. In this way, the second light-emitting layer 4G emits light.

Further, for example, the third charge transport layer 6 blocks the first charge injected from the first electrode 2G from being transported to the third light-emitting layer 4B. In this way, light emission of the third light-emitting layer 4B can be suppressed in the second light-emitting region 101G. In this way, color mixing in the second light-emitting region 101G can be suppressed.

Subsequently, the third light-emitting region 101B will be described.

The third light-emitting region 101B is, for example, a region that emits light at the light emission peak wavelength being the third wavelength (for example, blue) in the light-emitting device 100. The third light-emitting region 101B corresponds to, for example, a light-emitting element (for example, a blue light-emitting element) that emits light at the light emission peak wavelength being the third wavelength in the light-emitting device 100. The third light-emitting region 101B has a structure in which the substrate 1, the first electrode 2R, the first charge transport layer 3, the third light-emitting layer 4B, the fourth charge transport layer 7, and the second electrode 8 are layered in this order. In other words, the third light-emitting region 101B has a structure in which each of the layers is disposed between the first electrode 2 and the second electrode 8 disposed so as to face the first electrode 2. Note that the first electrode 2B is similar to the first electrode 2R.

Further, the third light-emitting region 101B has a configuration in which the first electrode 2G is replaced with the first electrode 2B, and the second light-emitting layer 4G and the third charge transport layer 6 are not provided in the configuration of the second light-emitting region 101G.

Furthermore, a bank 9 that isolates each of the light-emitting regions 101R, 101G, and 101B is provided in the light-emitting device 100 in the present embodiment.

Moreover, in the light-emitting device 100 in the present embodiment, the first electrodes 2R, 2G, and 2B are disposed at intervals on the substrate 1.

Each of the first charge transport layer 3, the second charge transport layer 5, the third charge transport layer 6, and the fourth charge transport layer 7 may be a hole transport layer or an electron transport layer.

Examples of a material forming the hole transport layer include a material including one or more types selected from the group consisting of an oxide, a nitride, or a carbide including any one or more of Zn, Cr, Ni, Ti, Nb, Al, Si, Mg, Ta, Hf, Zr, Y, La, and Sr, a material such as 4,4′,4″-tris(9-carbazole)triphenylamine (TCTA), 4,4′-bis[N-(1-naphthyl)-N-phenyl-amino]-biphenyl (NPB), zincphthalocyanine (ZnPC), triphenyldiamine (TPD), 1,3-bis(N-carbazolyl)benzene (mCP), di[4-(N,N-ditolylamino)phenyl]cyclohexane (TAPC), 4,4′-bis(carbazole-9-yl)biphenyl (CBP), 2,3,6,7,10,11-hexacyano-1,4,5,8,9,12-hexaazatriphenylene (HATCN), and MoO₃, a hole transport organic material such as poly(N-vinylcarbazole) (PVK), poly(2,7-(9,9-di-n-octylfluorene)-(1,4-phenylene-((4-sec-butylphenyl)imino)-1,4-phenylene (TFB), poly(triphenylamine) derivative (Poly-TPD), and poly(3,4-ethylenedioxythiophene)/poly (4-styrenesulfonic acid) (PEDOT-PSS), and the like. One type of these hole transport materials may be used, or two or more types thereof may be mixed and used as appropriate.

For example, an electron transport material such as zinc oxide (for example, ZnO), titanium oxide (for example, TiO₂), strontium oxide titanium (for example, SrTiO₃), lithium zirconium oxide (LZO), In₂O₃, CdS, LZO, SiTe, SiSe, SiS, ZrO₂, and 2,2′,2″-(1,3,5-benzenetriyl)tris(1-phenyl-1H-benzimidazole) (TPBi), and a fullerene derivative such as phenyl-C₆₁-methylester butyrate (PCBM) and bisindene C₆₀ (ICBA) is used as a material forming the electron transport layer. One type of these electron transport materials may be used, or two or more types thereof may be mixed and used as appropriate.

The materials forming the hole transport layer and the electron transport layer are selected as appropriate according to the configuration and characteristics of the light-emitting device 100.

According to the configuration described above, the light-emitting device 100 in the present embodiment emits light of a color in each of the light-emitting regions 101R, 101G, and 101B.

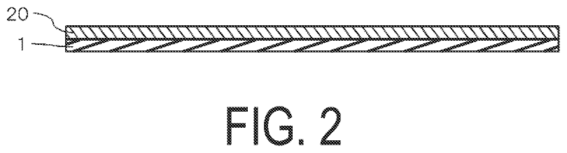

Next, an example of a manufacturing method of the light-emitting device in the disclosure will be described with reference to FIGS. 2 to 15.

First, as illustrated in FIG. 2, a first electrode layer 20 is formed on the substrate 1 (S1). The first electrode layer 20 can be formed by, for example, sputtering, an application method, or the like.

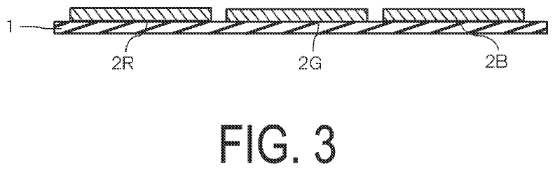

Next, as illustrated in FIG. 3, the first electrode layer 20 is patterned into the first electrodes 2R, 2G, and 2B by etching or the like (S2). The first electrodes 2R, 2G, and 2B are disposed at intervals on the substrate 1.

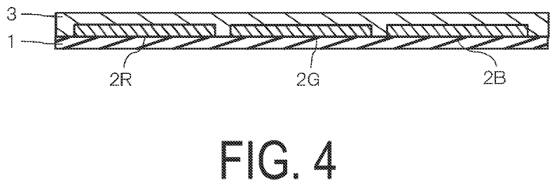

Next, as illustrated in FIG. 4, the first charge transport layer 3 is formed on the substrate 1, more specifically, the first electrodes 2R, 2G, and 2B formed on the substrate 1 (S3). The first charge transport layer 3 can be formed by, for example, an application method, sputtering, or the like. Note that a base material in which the first electrodes 2R, 2G, and 2B and the first charge transport layer 3 are disposed on the substrate 1 can be manufactured in this step.

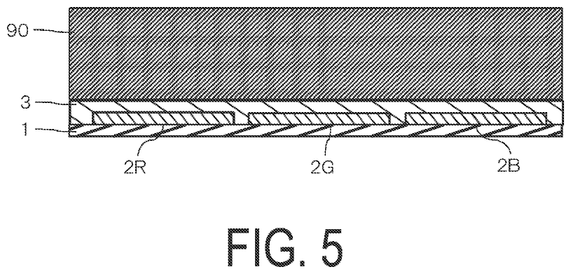

Next, as illustrated in FIG. 5, a resist layer 90 is formed on the first charge transport layer 3 in the base material (S5). The resist layer 90 can be formed by, for example, applying a positive-working photoresist.

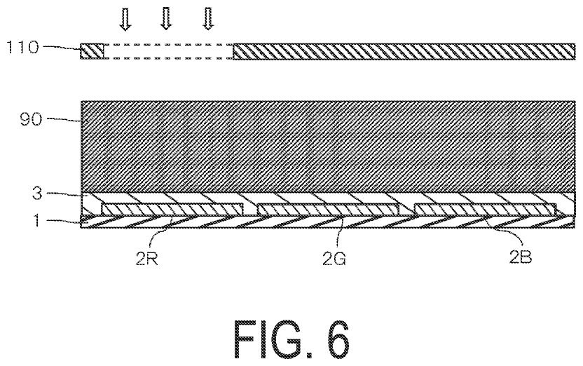

Next, as illustrated in FIG. 6, the resist layer 90 is exposed via a photomask 110 (S6). More specifically, in the exposure step of S6, at least a part of a portion of the resist layer 90 located on the first electrode 2R, that is, at least a part of a region of the resist layer 90 corresponding to the first electrode 2R in a plan view is exposed.

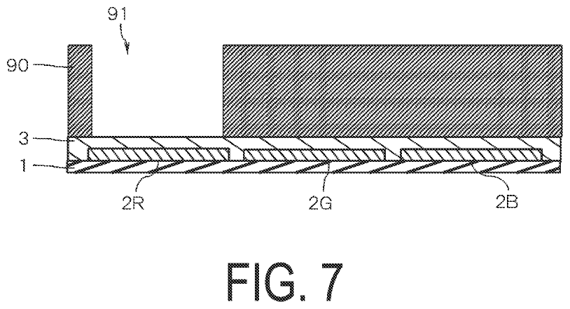

Next, as illustrated in FIG. 7, the exposed portion, that is, at least a part of the portion of the resist layer 90 located on the first electrode 2R is removed by development with a developing solution, for example (S10). In this way, a removed portion 91 is formed in the resist layer 90. The base material, specifically the first charge transport layer 3 is exposed through the removed portion 91.

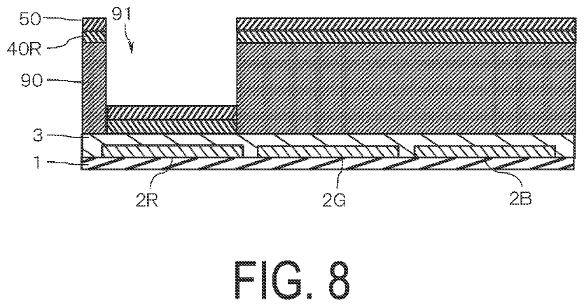

Next, as illustrated in FIG. 8, a first light-emitting layer 40 and a second charge transport layer 50 are formed (S11). More specifically, a first light-emitting layer 40R is formed on the resist layer 90 that has been partly removed in S10. The first light-emitting layer 40R can be formed by an application method using an application solution including quantum dots, for example. An electron transport material, a hole transport layer material, a resist material, a silane coupling agent, a thermosetting resin, and the like may be included in the application solution. Subsequently, the second charge transport layer 50 is further formed on the first light-emitting layer 40R. The second charge transport layer 50 can be formed by, for example, a method similar to that of the first charge transport layer 3.

Note that, in the removed portion 91 described above, the first light-emitting layer 40R and the second charge transport layer 50 are formed on the first charge transport layer 3. The first light-emitting layer 40R and the second charge transport layer 50 formed in the removed portion 91 remain in the end to serve as the first light-emitting layer 4R and the second charge transport layer 5 in the first light-emitting region 101R, respectively.

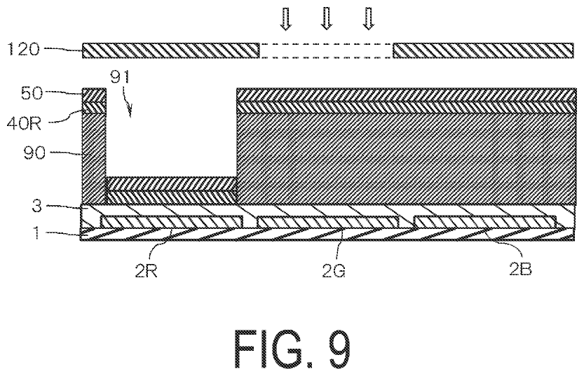

Next, as illustrated in FIG. 9, the resist layer 90 is exposed via a photomask 120 (S12). More specifically, in the exposure step of S12, at least a part of a portion of the resist layer 90 located on the first electrode 2G, that is, at least a part of a region of the resist layer 90 corresponding to the first electrode 2G in the plan view is exposed.

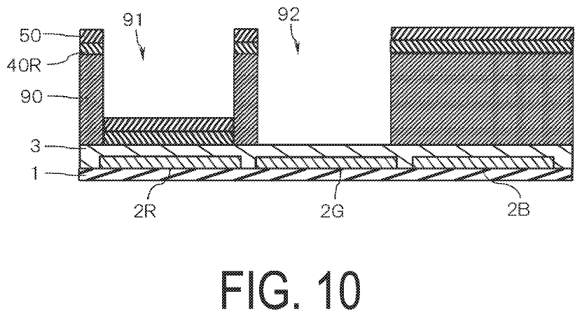

Next, as illustrated in FIG. 10, the exposed portion, that is, at least a part of the portion of the resist layer 90 located on the first electrode 2G is removed by development with a developing solution, for example (S13). In S13, a portion of the first light-emitting layer 40R and the second charge transport layer 50 corresponding to the exposed portion is removed by lift-off. In this way, a removed portion 92 is formed in the resist layer 90. The base material, specifically the first charge transport layer 3 is exposed in the removed portion 92. Further, a portion of the resist layer 90 located between the first electrode 2R and the first electrode 2G in the plan view remains. Note that, for example, for the remaining portion of the resist layer 90, a portion located on an end portion of the first electrode 2R on the first electrode 2G side and an end portion of the first electrode 2G on the first electrode 2R side in the plan view remains.

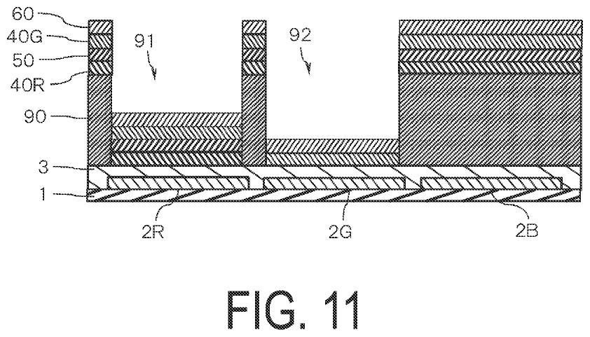

Next, as illustrated in FIG. 11, a second light-emitting layer 40G and a third charge transport layer 60 are formed on the second charge transport layer 50 (S14). More specifically, the second light-emitting layer 40G is formed on the resist layer 90 from which the removed portion 91 and the removed portion 92 have been removed in S13. For example, the second light-emitting layer 40G can be formed as in forming the first light-emitting layer 40R. Subsequently, the third charge transport layer 60 is further formed on the second light-emitting layer 40G. The third charge transport layer 60 can be formed by, for example, a method similar to that of the first charge transport layer 3.

Note that, in the removed portion 91 described above, the second light-emitting layer 40G and the third charge transport layer 60 are formed on the second charge transport layer 50. The second light-emitting layer 40G and the third charge transport layer 60 formed in the removed portion 91 remain in the end to serve as the second light-emitting layer 4G and the third charge transport layer 6 in the first light-emitting region 101R, respectively.

Further, in the removed portion 92 described above, the second light-emitting layer 40G and the third charge transport layer 60 are formed on the first charge transport layer 3. The second light-emitting layer 40G and the third charge transport layer 60 formed in the removed portion 92 remain in the end to serve as the second light-emitting layer 4G and the third charge transport layer 6 in the second light-emitting region 101G, respectively.

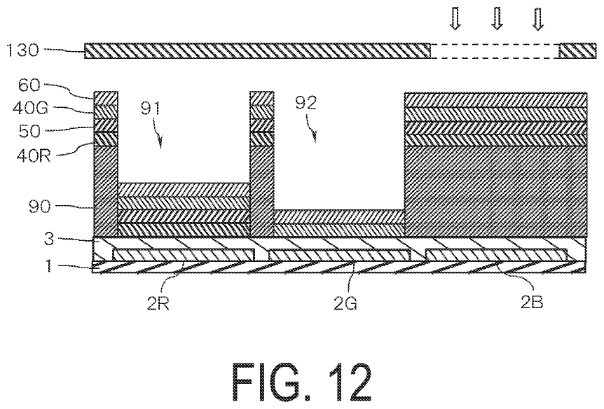

Next, as illustrated in FIG. 12, the resist layer 90 is exposed via a photomask 130 (S15). More specifically, in the exposure step of S15, at least a part of a portion of the resist layer 90 located on the first electrode 2B, that is, at least a part of a region of the resist layer 90 corresponding to the first electrode 2B in the plan view is exposed.

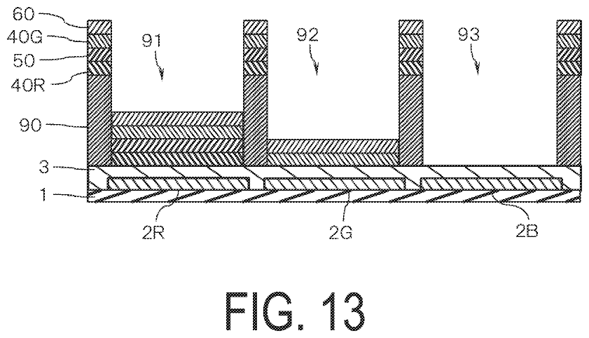

Next, as illustrated in FIG. 13, the exposed portion, that is, at least a part of the portion of the resist layer 90 located on the first electrode 2B is removed by development with a developing solution, for example (S16). In S16, a portion of the first light-emitting layer 40R, the second charge transport layer 50, the second light-emitting layer 20G, and the third charge transport layer 60 corresponding to the exposed portion is removed by lift-off. In this way, a removed portion 93 is formed in the resist layer 90. The base material, specifically, the first charge transport layer 3 is exposed in the removed portion 93. Further, a portion of the resist layer 90 located between the first electrode 2G and the first electrode 2B in the plan view remains. Note that, for example, for the remaining portion of the resist layer 90, a portion located on an end portion of the first electrode 2G on the first electrode 2B side and an end portion of the first electrode 2B on the first electrode 2G side in the plan view remains. Furthermore, since the second light-emitting layer 4G and the third charge transport layer 6 are formed on the first light-emitting layer 4R and the second charge transport layer 5 in the first light-emitting region 101R, damage to the first light-emitting layer 4R and the second charge transport layer 5 by the developing solution can be suppressed in the development described above.

Furthermore, for example, the first electrode 2B and the first electrode 2R are disposed adjacent to each other by repeatedly disposing the first electrode 2R, the first electrode 2G, and the first electrode 2B, and a portion of the resist layer 90 located between the first electrode 2B and the first electrode 2R in the plan view can also remain. In this case, for the remaining portion of the resist layer 90, a portion located on an end portion of the first electrode 2B on the first electrode 2R side and an end portion of the first electrode 2R on the first electrode 2B side in the plan view remains.

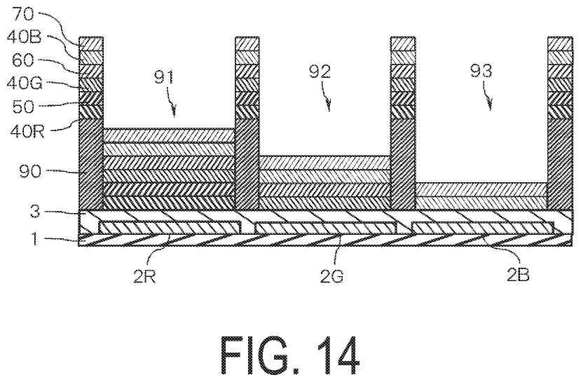

Next, as illustrated in FIG. 14, a third light-emitting layer 40B and a fourth charge transport layer 70 are formed on the third charge transport layer 60 (S17). More specifically, the third light-emitting layer 40B is formed on the resist layer 90 from which the removed portion 91, the removed portion 92, and the removed portion 93 have been removed in S16. For example, the third light-emitting layer 40B can be formed as in forming the first light-emitting layer 40R. Subsequently, the fourth charge transport layer 70 is further formed on the third light-emitting layer 40B. The fourth charge transport layer 70 can be formed by, for example, a method similar to that of the first charge transport layer 3.

Note that, in the removed portion 91 described above, the third light-emitting layer 40B and the fourth charge transport layer 70 are formed on the third charge transport layer 60. The third light-emitting layer 40B and the fourth charge transport layer 70 formed in the removed portion 91 remain in the end to serve as the third light-emitting layer 4B and the fourth charge transport layer 7 in the first light-emitting region 101R, respectively.

Further, in the removed portion 92 described above, the third light-emitting layer 40B and the fourth charge transport layer 70 are formed on the third charge transport layer 60. The third light-emitting layer 40B and the fourth charge transport layer 70 formed in the removed portion 92 remain in the end to serve as the third light-emitting layer 4B and the fourth charge transport layer 7 in the second light-emitting region 101G, respectively.

Furthermore, in the removed portion 93 described above, the third light-emitting layer 40B and the fourth charge transport layer 70 are formed on the first charge transport layer 3. The third light-emitting layer 40B and the fourth charge transport layer 70 formed in the removed portion 93 remain in the end to serve as the third light-emitting layer 4B and the fourth charge transport layer 7 in the third light-emitting region 101B, respectively.

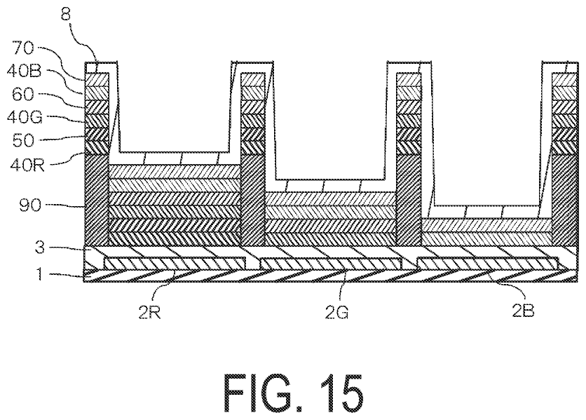

Next, as illustrated in FIG. 15, the second electrode 8 is formed on the fourth charge transport layer 70 (S17). The second electrode 8 can be formed similarly to the first electrode layer 20.

Furthermore, by performing postbaking after the removed portion 93 is formed in the resist layer 90, that is, performing postbaking on the remaining portion of the resist layer 90, the remaining portion of the remaining resist layer 90 can be cured and remain as a permanent film. The remaining portion of the resist layer 90 after the postbaking can be the bank 9.

As described above, the light-emitting device 100 according to the present embodiment can be manufactured.

According to the method described above, the number of times of the resist removing step decreases; thus, damage to the light-emitting layer and the like by development can be suppressed, and reliability of the light-emitting device can be improved.

Further, for a modified example, for example, one or more of the first light-emitting layer 40R, the second charge transport layer 5, the second light-emitting layer 40G, the third charge transport layer 6, the third light-emitting layer 40B, and the fourth charge transport layer 7 that are formed in regions of the resist layer 90 between the first electrode 2R, the first electrode 2G, and the first electrode 2B can be lifted off by performing halftone exposure on at least one region of the regions of the resist layer 90 between the first electrode 2R, the first electrode 2G, and the first electrode 2B in the exposure described above. The halftone exposure can be performed by using a halftone mask for exposure in a halftone of at least one region of the regions of the resist layer 90 between the first electrode 2R, the first electrode 2G, and the first electrode 2B instead of the photomask 120 in S6 and the photomask 130 in S12. Furthermore, the halftone exposure may be performed before the postbaking described above is performed, for example.

Further, in the method described above, the light-emitting layers 4R, 3G, and 3B are preferably formed in an order from the light-emitting layer having a longer wavelength.

As a first example and a second example, a more specific configuration of the light-emitting device 100 described above will be described below.

### First Example

The light-emitting device 100 according to the first example has a configuration in which the first electrodes 2R, 2G, and 2B are anodes, the first charge transport layer 3 is a hole transport layer, the second charge transport layer 5 is a first electron transport layer, the third charge transport layer 6 is a second electron transport layer, the fourth charge transport layer 7 is a third electron transport layer, and the second electrode 8 is a cathode. Other configurations are as described above.

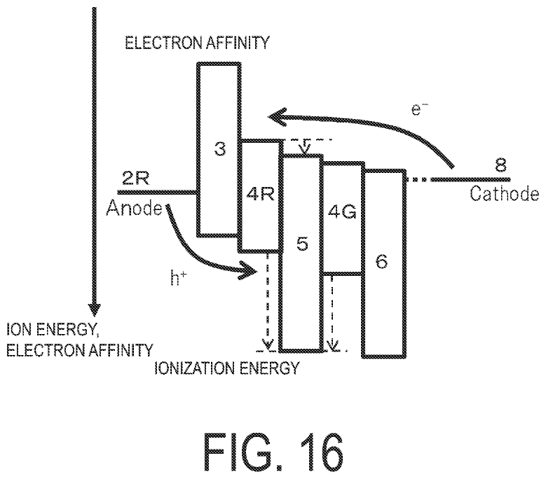

For example, as illustrated in FIG. 16, in the light-emitting device 100 according to the present example, the second charge transport layer (first electron transport layer) 5 preferably has ionization energy set higher than ionization energy of the first light-emitting layer 4R. Furthermore, the second charge transport layer 5 preferably has the ionization energy set lower than ionization energy of the second light-emitting layer 4G. In other words, the second charge transport layer 5 preferably has the ionization energy set higher than both of the ionization energy of the first light-emitting layer 4R and the ionization energy of the second light-emitting layer 4G. In this way, a hole injected from the first electrode (anode) 2R via the first charge transport layer (hole transport layer) 3 can be confined in the first light-emitting layer 4R, and luminous efficiency in the first light-emitting region 101R can be improved. In other words, in the first example, the second charge transport layer (first electron transport layer) 5 can be referred to as a hole blocking layer. Furthermore, in the first light-emitting region 101R, the second charge transport layer (first electron transport layer) 5 blocks the hole, and thus it is difficult for the hole to be injected into the second light-emitting layer 4G. In other words, the second light-emitting layer 4G cannot emit light; thus, only the first light-emitting layer 4R emits light in the first light-emitting region 101R, and color mixing can be suppressed regardless of presence of the second light-emitting layer 4G and the third light-emitting layer 4B.

Further, as illustrated in FIG. 16, in the present example, the second charge transport layer (first electron transport layer) 5 preferably has an electron affinity equal to or greater than an electron affinity of the first light-emitting layer 4R, for example. In this way, in the first light-emitting region 101R, an electron injected from the second electrode (cathode) 8 can be easily transported to the first light-emitting layer 4R, and luminous efficiency in the first light-emitting region 101R can be improved.

Note that a specific combination of preferred materials of the first light-emitting layer 4R and the second charge transport layer (first electron transport layer) 5 in the present example is as follows.

For example, when the material of the first light-emitting layer 4R is CdSe or CdZnSe (electron affinity: approximately 4.3 eV and ionization energy: approximately 6.2 eV) being a quantum dot that emits red light, the material of the second charge transport layer 5 is preferably at least one type selected from In₂O₃ (electron affinity: 4.3 eV and ionization energy: 8.2 eV), CdS (electron affinity: 4.45 eV and ionization energy: 6.85 eV), and LZO (electron affinity: 4.4 eV and ionization energy: 7.6 eV).

Further, for example, when the material of the first light-emitting layer 4R is CdSe or CdZnSe (electron affinity: approximately 3.9 eV and ionization energy: approximately 6.2 eV) being a quantum dot that emits green light, the material of the second charge transport layer 5 is preferably at least one type selected from In₂O₃ (electron affinity: 4.3 eV and ionization energy: 8.2 eV), CdS (electron affinity: 4.45 eV and ionization energy: 6.85 eV), LZO (electron affinity: 4.4 eV and ionization energy: 7.6 eV), SiS (electron affinity: 3.98 eV and ionization energy: 6.98 V), ZnO (electron affinity: 4.0 eV and ionization energy: 7.5 eV), PCBM (electron affinity: 4.0 eV and ionization energy: 6.5 eV), and TiO₂ (electron affinity: 4.2 eV and ionization energy: 7.4 eV).

Furthermore, for example, when the material of the first light-emitting layer 4R is InP (electron affinity: approximately 3.6 eV and ionization energy: approximately 5.5 eV) being a quantum dot that emits red light, the material of the second charge transport layer 5 is preferably at least one type selected from In₂O₃ (electron affinity: 4.3 eV and ionization energy: 8.2 eV), CdS (electron affinity: 4.45 eV and ionization energy: 6.85 eV), LZO (electron affinity: 4.4 eV and ionization energy: 7.6 eV), SiS (electron affinity: 3.98 eV and ionization energy: 6.98 V), ZnO (electron affinity: 4.0 eV and ionization energy: 7.5 eV), PCBM (electron affinity: 4.0 eV and ionization energy: 6.5 eV), TiO₂ (electron affinity: 4.2 eV and ionization energy: 7.4 eV), SiTe (electron affinity: 3.66 eV and ionization energy: 6.09 V), SiSe (electron affinity: 3.72 eV and ionization energy: 6.62 V), and ICBA (electron affinity: 3.7 eV and ionization energy: 6 eV).

Moreover, for example, when the material of the first light-emitting layer 4R is InP (electron affinity: approximately 3.6 eV and ionization energy: approximately 5.5 eV) being a quantum dot that emits green light, the material of the second charge transport layer 5 is preferably at least one type selected from In₂O₃ (electron affinity: 4.3 eV and ionization energy: 8.2 eV), CdS (electron affinity: 4.45 eV and ionization energy: 6.85 eV), LZO (electron affinity: 4.4 eV and ionization energy: 7.6 eV), SiS (electron affinity: 3.98 eV and ionization energy: 6.98 V), ZnO (electron affinity: 4.0 eV and ionization energy: 7.5 eV), PCBM (electron affinity: 4.0 eV and ionization energy: 6.5 eV), TiO₂ (electron affinity: 4.2 eV and ionization energy: 7.4 eV), SiTe (electron affinity: 3.66 eV and ionization energy: 6.09 V), SiSe (electron affinity: 3.72 eV and ionization energy: 6.62 V), and ICBA (electron affinity: 3.7 eV and ionization energy: 6 eV).

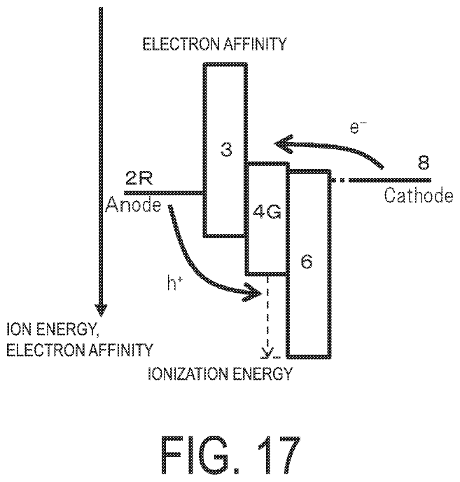

Furthermore, for example, as illustrated in FIG. 17, in the present example, the third charge transport layer (second electron transport layer) 6 preferably has ionization energy set higher than the ionization energy of the second light-emitting layer 4G. In this way, in the second light-emitting region 101G, a hole injected from the first electrode (anode) 2G via the first charge transport layer (hole transport layer) 3 can be confined in the second light-emitting layer 4G, and luminous efficiency in the second light-emitting region 101G can be improved. In other words, in the present example, the third charge transport layer (second electron transport layer) 6 can be referred to as a hole blocking layer. Furthermore, in the third light-emitting layer 4B, the hole is blocked by the third charge transport layer (second electron transport layer) 6, and thus, in the second light-emitting region 101G, light emission of the third light-emitting layer 4B can be suppressed, and color mixing can be suppressed.

Moreover, in the present example, the third charge transport layer (second electron transport layer) 6 preferably has an electron affinity equal to or greater than an electron affinity of the third light-emitting layer 4B. In this way, in the second light-emitting region 101G, an electron injected from the second electrode (cathode) 8 can be easily transported to the second light-emitting layer 4G, and luminous efficiency in the second light-emitting region 101G can be improved.

### Second Example

The light-emitting device 100 according to the present example has a configuration in which the first electrodes 2R, 2G, and 2B are cathodes, the first charge transport layer 3 is an electron transport layer, the second charge transport layer 5 is a first hole transport layer, the third charge transport layer 6 is a second hole transport layer, the fourth charge transport layer 7 is a third hole transport layer, and the second electrode 8 is an anode. Other configurations are as described above.

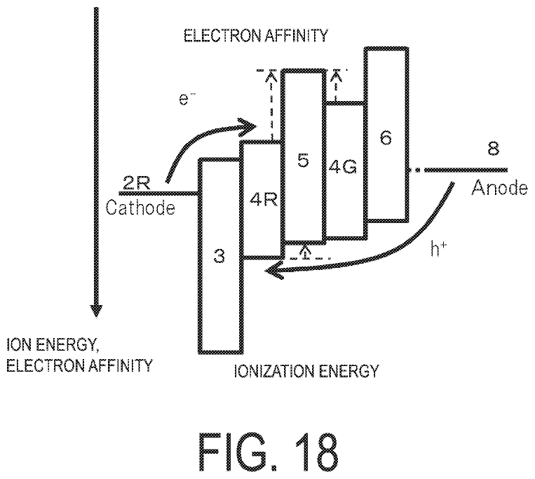

As illustrated in FIG. 18, in the light-emitting device 100 according to the present example, the second charge transport layer (first hole transport layer) 5 preferably has an electron affinity set lower than an electron affinity of the second light-emitting layer 4G, for example. Furthermore, the second charge transport layer 5 preferably has the electron affinity set lower than an electron affinity of the first light-emitting layer 4R. In other words, the second charge transport layer 5 preferably has the electron affinity set lower than both of the electron affinity of the first light-emitting layer 4R and the electron affinity of the second light-emitting layer 4G. In this way, in the first light-emitting region 101R, an electron injected from the first electrode (cathode) 2R can be confined in the first light-emitting layer 4R, and luminous efficiency in the first light-emitting region 101R can be improved. In other words, in the present example, the second charge transport layer (first hole transport layer) 5 can be referred to as an electron blocking layer. Furthermore, in the first light-emitting region 101R, the second charge transport layer (first hole transport layer) 5 blocks the electron, and thus it is difficult for the electron to be injected into the second light-emitting layer 4G. In other words, the second light-emitting layer 4G cannot emit light; thus, only the first light-emitting layer 4R emits light in the first light-emitting region 101R, and color mixing can be suppressed regardless of presence of the second light-emitting layer 4G and the third light-emitting layer 4B.

Further, for example, as illustrated in FIG. 18, in the light-emitting device 100 according to the present example, the second charge transport layer (first hole transport layer) 5 preferably has ionization energy equal to or less than ionization energy of the first light-emitting layer 4R. In this case, in the first light-emitting region 101R, a hole injected from the second electrode (anode) 8 can be easily transported to the first light-emitting layer 4R, and luminous efficiency in the first light-emitting region 101R can be improved.

Note that a specific combination of preferred materials of the first light-emitting layer 4R and the second charge transport layer (first hole transport layer) 5 in the present example is as follows.

For example, when the material of the first light-emitting layer 4R is CdSe or CdZnSe (electron affinity in a case of, for example, red light emission: approximately 4.3 eV, electron affinity in a case of, for example, green light emission: approximately 3.9 eV, and ionization energy: 6.2 eV) being a quantum dot, the material of the second charge transport layer 5 is preferably at least one type selected from poly-TPD (electron affinity: 2.3 eV and ionization energy: 5.2 eV), TFB (electron affinity: 2.3 eV and ionization energy: 5.3 eV), TAPC (electron affinity: 2.0 eV and ionization energy: 5.5 eV), NPB (electron affinity: 2.4 eV and ionization energy: 5.5 eV), TPD (electron affinity: 2.0 eV and ionization energy: 5.5 eV), NiO (electron affinity: 2.5 eV and ionization energy: 6.2 eV), mCP (electron affinity: 2.7 eV and ionization energy: 6.2 eV), CBP (electron affinity: 2.9 eV and ionization energy: 6.1 eV), TCTA (electron affinity: 2.4 eV and ionization energy: 5.9 eV), and PVK (electron affinity: 2.2 eV and ionization energy: 5.8 eV).

Furthermore, for example, when the material of the first light-emitting layer 4R is InP (electron affinity in a case of, for example, red light emission: approximately 3.6 eV, electron affinity in a case of, for example, green light emission: approximately 5.5 eV, and ionization energy: 5.5 eV) being a quantum dot, the material of the second charge transport layer 5 is preferably at least one type selected from poly-TPD (electron affinity: 2.3 eV and ionization energy: 5.2 eV), TFB (electron affinity: 2.3 eV and ionization energy: 5.3 eV), TAPC (electron affinity: 2.0 eV and ionization energy: 5.5 eV), NPB (electron affinity: 2.4 eV and ionization energy: 5.5 eV), and TPD (electron affinity: 2.0 eV and ionization energy: 5.5 eV).

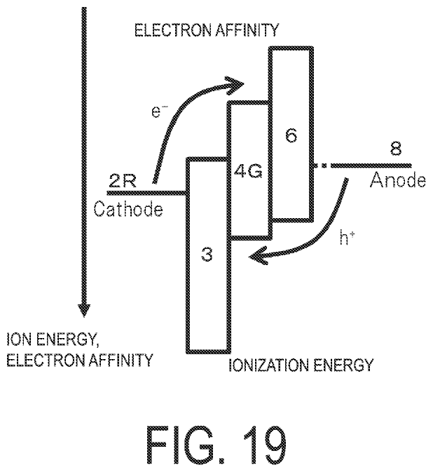

Furthermore, as illustrated in FIG. 19, in the present example, the third charge transport layer (second hole transport layer) 6 preferably has an electron affinity set lower than an electron affinity of the second light-emitting layer 4G, for example. In this case, in the second light-emitting region 101G, an electron injected from the first electrode (cathode) 2G can be confined in the second light-emitting layer 4G, and luminous efficiency in the second light-emitting region 101G can be improved. In other words, in the present example, the third charge transport layer (second electron transport layer) 6 can be referred to as an electron blocking layer. Furthermore, in the third light-emitting layer 4B, the electron is blocked by the third charge transport layer (second hole transport layer) 6; thus, in the second light-emitting region 101G, light emission of the third light-emitting layer 4B can be suppressed, and color mixing can be suppressed.

Moreover, in the light-emitting device 100 according to the present example, the third charge transport layer (second hole transport layer) 6 preferably has ionization energy equal to or less than ionization energy of the second light-emitting layer 2G. In this way, in the second light-emitting region 101G, a hole injected from the second electrode (anode) 8 can be easily transported to the second light-emitting layer 4G, and luminous efficiency in the second light-emitting region 101G can be improved.

The present invention is not limited to the embodiments described above, and may be substituted with a configuration that is substantially the same as the configuration described in the embodiments described above, a configuration that achieves the same action and effect, or a configuration capable of achieving the same object.

1. A light-emitting device comprising:
a first light-emitting region in which a light emission peak wavelength is a first wavelength;
a second light-emitting region in which a light emission peak wavelength is a second wavelength shorter than the first wavelength;
a cathode disposed in the first light-emitting region and the second light-emitting region;
an anode facing the cathode in the first light-emitting region and the second light-emitting region;
a second light-emitting layer disposed between the cathode and the anode in the first light-emitting region and the second light-emitting region and having a light emission peak wavelength being the second wavelength;
a first light-emitting layer disposed between the anode and the second light-emitting layer at least in the first light-emitting region and having a light emission peak wavelength being the first wavelength; and
a first electron transport layer disposed between the first light-emitting layer and the second light-emitting layer in the first light-emitting region and having ionization energy higher than both of ionization energy of the first light-emitting layer and ionization energy of the second light-emitting layer.

2. The light-emitting device according to claim 1,
wherein an electron affinity of the first electron transport layer is equal to or greater than an electron affinity of the first light-emitting layer.

3. The light-emitting device according to claim 2,
wherein, when a material of the first light-emitting layer is CdSe or CdZnSe being a quantum dot that emits red light, a material of the first electron transport layer is at least one type selected from In₂O₃, CdS, and LZO,
when a material of the first light-emitting layer is CdSe or CdZnSe being a quantum dot that emits green light, a material of the first electron transport layer is at least one type selected from In₂O₃, CdS, LZO, SiS, ZnO, PCBM, and TiO₂,
when a material of the first light-emitting layer is InP being a quantum dot that emits red light, a material of the first electron transport layer is at least one type selected from In₂O₃, CdS, LZO, SiS, ZnO, PCBM, and TiO₂, and
when a material of the first light-emitting layer is InP being a quantum dot that emits green light, a material of the first electron transport layer is at least one type selected from In₂O₃, CdS, LZO, SiS, ZnO, PCBM, TiO₂, SiTe, SiSe, and ICBA.

4. A light-emitting device comprising:
a first light-emitting region in which a light emission peak wavelength is a first wavelength;
a second light-emitting region in which a light emission peak wavelength is a second wavelength shorter than the first wavelength;
a cathode disposed in the first light-emitting region and the second light-emitting region;
an anode facing the cathode in the first light-emitting region and the second light-emitting region;
a second light-emitting layer disposed between the cathode and the anode in the first light-emitting region and the second light-emitting region and having a light emission peak wavelength being the second wavelength;
a first light-emitting layer disposed between the cathode and the second light-emitting layer at least in the first light-emitting region and having a light emission peak wavelength being the first wavelength; and
a first hole transport layer disposed between the first light-emitting layer and the second light-emitting layer in the first light-emitting region and having an electron affinity lower than both of an electron affinity of the first light-emitting layer and an electron affinity of the second light-emitting layer.

5. The light-emitting device according to claim 4,
wherein ionization energy of the first hole transport layer is equal to or less than ionization energy of the first light-emitting layer.

6. The light-emitting device according to claim 5,
wherein, when a material of the first light-emitting layer is CdSe or CdZnSe being a quantum dot, a material of the first hole transport layer is at least one type selected from poly-TPD, TFB, TAPC, NPB, TPD, NiO, mCP, CBP, TCTA, and PVK, and
when a material of the first light-emitting layer is InP being a quantum dot, a material of the first hole transport layer is at least one type selected from poly-TPD, TFB, TAPC, NPB, and TPD.

7. A manufacturing method of a light-emitting device, comprising:
forming a resist layer on a base material;
removing a portion of the resist layer;
forming a first light-emitting layer on the base material on which the portion of the resist layer has been removed;
forming a charge transport layer covering the first light-emitting layer; and
removing a portion of the resist layer covered by the charge transport layer, and forming a second light-emitting layer on the removed portion.

8. The manufacturing method of a light-emitting device, according to claim 7,
wherein a positive-working resist layer is formed as the resist layer.

9. The manufacturing method of a light-emitting device, according to claim 8,
wherein a portion of the resist layer is exposed and the exposed portion of the resist layer is removed.

10. The manufacturing method of a light-emitting device, according to claim 7,
wherein the second light-emitting layer is also formed on the first light-emitting layer.

11. The manufacturing method of a light-emitting device, according to claim 7,
wherein as the second light-emitting layer, a light-emitting layer having a light emission peak wavelength shorter than a light emission peak wavelength of the first light-emitting layer is formed.

12. The manufacturing method of a light-emitting device, according to claim 7,
wherein a member including a substrate and a plurality of electrodes disposed at intervals on the substrate is used as the base material.

13. The manufacturing method of a light-emitting device, according to claim 12, further comprising:
removing at least a part of a portion of the resist layer located on one electrode of the plurality of electrodes before forming the first light-emitting layer; and
removing, before forming the second light-emitting layer, at least a part of a portion of the resist layer covered by the charge transport layer, the portion being located on another electrode adjacent to the one electrode of the plurality of electrodes, while causing at least a part of a portion of the resist layer located between the one electrode and the another electrode in a plan view to remain.

14. The manufacturing method of a light-emitting device, according to claim 13, further comprising:
curing a remaining portion of the resist layer.

15. The manufacturing method of a light-emitting device, according to claim 13,
wherein a portion of the resist layer located on an end portion of the one electrode on the another electrode side and an end portion of the another electrode on the one electrode side is caused to remain, in addition to the portion located between the one electrode and the another electrode in the plan view.

16. The manufacturing method of a light-emitting device, according to claim 13,
wherein a positive-working resist layer is formed as the resist layer, and
a portion of the resist layer located in a region in which the remaining portion is formed is partly exposed, and then development of the resist layer is performed.
